(19) United States
(12) Patent Application Publication
(10) Pub. No.: US 2016/0348232 A1
(43) Pub. Date: Dec. 1, 2016

(54) ANODE LAYER ION SOURCE AND ION BEAM SPUTTER DEPOSITION MODULE

(71) Applicant: National Taiwan University of Science and Technology, Taipei City (TW)

(72) Inventor: Liang-Chiun CHAO, TAIPEI CITY (TW)

(21) Appl. No.: 15/163,659

(22) Filed: May 24, 2016

(30) Foreign Application Priority Data
May 29, 2015 (TW) 104117375

(51) Int. Cl. C23C 14/46

(52) U.S. Cl. CPC C23C 14/46

(57) ABSTRACT

An anode layer ion source includes a magnetic field generating member, an upper cathode electrode, a lower cathode electrode, a case member, and an anode electrode. The magnetic field generating member generates a magnetic field. The upper cathode electrode and the lower cathode respectively have two end members and form an opening there between. The two end members are two ends of the opening and guide the magnetic field to the opening, and the magnetic field in the openings is substantially parallel to the connection of two ends of the opening. The case member, the upper cathode electrode, and the lower cathode electrode form an accommodating cavity. The anode electrode is disposed in the accommodating cavity and generates an electric field to the opening. The electric field in the opening is substantially perpendicular to the magnetic field in the opening.

### RELATED APPLICATIONS

This application claims priority to Taiwanese Application Serial Number 104117375, filed May 29, 2015, which are herein incorporated by reference.

### BACKGROUND

1. Technical Field

The present disclosure relates to an anode layer ion source and an ion beam sputter deposition module.

2. Description of Related Art

Sputtering is a physical vapor deposition process whereby particles are ejected from a solid target material due to bombardment of the target by energetic ions. Sputtering generally is performed in a nearly vacuumed system filled with inert gas, such as argon, and the argon gas is ionized due to the high voltage electric field, such that the argon ions are generated and hit the target. Then, atoms or molecules that are ejected from the target material are deposited and form a thin film on the semiconductor wafer, glass, or ceramic. Because sputtering can be performed to form a thin film made of a material with a high melting point, and the composition of the target material can be maintained without change when an alloy thin film or a compound thin film is formed, sputtering is widely applied in the manufacturing of the semiconductor devices and the integrated circuits.

To further improve various characteristics of the sputtering process and the associated apparatuses, persons in the industry all endeavor to search for practical solutions. The application of the sputtering process and the associated apparatuses is one of many important research topics, and is also a target that needs to be improved in many related fields.

### SUMMARY

This disclosure provides a module that integrates an anode layer ion source with a sputtering target to minimize vacuum chamber volume and to enhance the sputtering efficiency.

In one aspect of the disclosure, an anode layer ion source is provided. The anode layer ion source includes a magnetic field generating member, a cathode electrode, a case member, and an anode electrode. The magnetic field generating member is configured to generate a magnetic field. The cathode electrode includes an upper cathode electrode and a lower cathode electrode. The upper cathode electrode has a first end member. The lower cathode electrode has a second end member. An opening is formed between the first end member and the second end member, and the first end member and the second end member are two ends of the opening. The cathode electrode guides the magnetic field generated by the magnetic field generating member to the opening, and the magnetic field in the opening is substantially parallel to the connection of the two ends of the opening. The case member and the cathode electrode form an accommodating cavity. The anode electrode is disposed in the accommodating cavity and configured to generate an electric field to the opening, and the electric field in the opening is substantially perpendicular to the magnetic field in the opening.

In one or more embodiments, potentials of the anode electrode and the cathode electrode are greater than zero.

In one or more embodiments, a potential of the upper cathode electrode is different from a potential of the lower cathode electrode that they act as electrostatic-magnetic wehnelt electrodes.

In one or more embodiments, the magnetic field generating member is a permanent magnet.

In one or more embodiments, the magnetic field generating member is an electromagnet.

In one or more embodiments, the cathode electrode is made of a material that is both magnetoconductive and electrical conductive.

In one or more embodiments, shapes of the first end member and the second end member are annular, oval or racetrack shaped.

In one or more embodiments, a normal of the opening is not perpendicular to a symmetry axis of the first end member.

In another aspect of the disclosure, an ion beam sputter deposition module is provided. The ion beam sputter deposition module includes a target and the anode layer ion source. The anode layer ion source is configured to provide an ion beam to be emitted on the target in an inclined angle.

In one or more embodiments, an incident angle in which the ion beam is emitted on the target is in a range from about 30° to about 65°.

Because the potential of the cathode electrode is greater than zero, the cathode electrode generates outwardly diverging electric fields. This cathode electrode act as wehnelt electrode. Therefore, when ions (for example, positively charged argon ions) move away from the anode electrode, at first some of the ions may move toward the cathode electrode. However, ions will be repelled by the cathode electrode due to the electric fields generated by the cathode electrode when the distance between the ions and the cathode electrode become smaller, such that the ions will not hit the cathode electrode. Therefore, because the ions do not hit the cathode electrode, the anode layer ion source will not overheated, and the cathode electrode will not be damaged by the hits of the ions. Meanwhile, because no ions are wasted due to the bombardment of the ions on the cathode electrode, the sputtering efficiency is effectively enhanced.

The upper cathode and the lower cathode electrode do not have to be at the same potential. The potential on each cathode electrode can be adjusted independently by individual power supplies to optimize sputter rate and minimize cathode erosion. Thus the upper cathode and the lower cathode act as asymmetric electrostatic-magnetic wehnelt electrodes.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic perspective view of an ion beam sputter deposition module utilizing an anode layer ion source according to one embodiment of this invention;

FIG. 2 is a cross-sectional view viewed along line 2-2 of FIG. 1;

FIG. 3 is a partially enlarged view of FIG. 2;

FIG. 4 is a schematic perspective view of the anode layer ion source according to another embodiment of this invention;

FIG. 5 is a film thickness to horizontal position figure of a thin film deposited on a substrate by the ion beam sputter deposition module according to one embodiment of this invention; and

FIG. 6 is a figure showing currents collected by the upper cathode electrode due to argon ion bombardment at various anode electrode voltages when the anode layer ion source is sputtering according to different embodiments of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

In other instances, well-known structures and devices are schematically depicted in order to simplify the drawings.

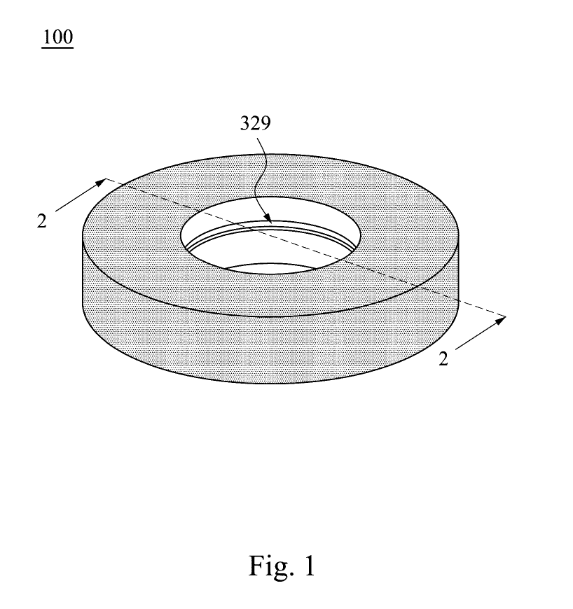

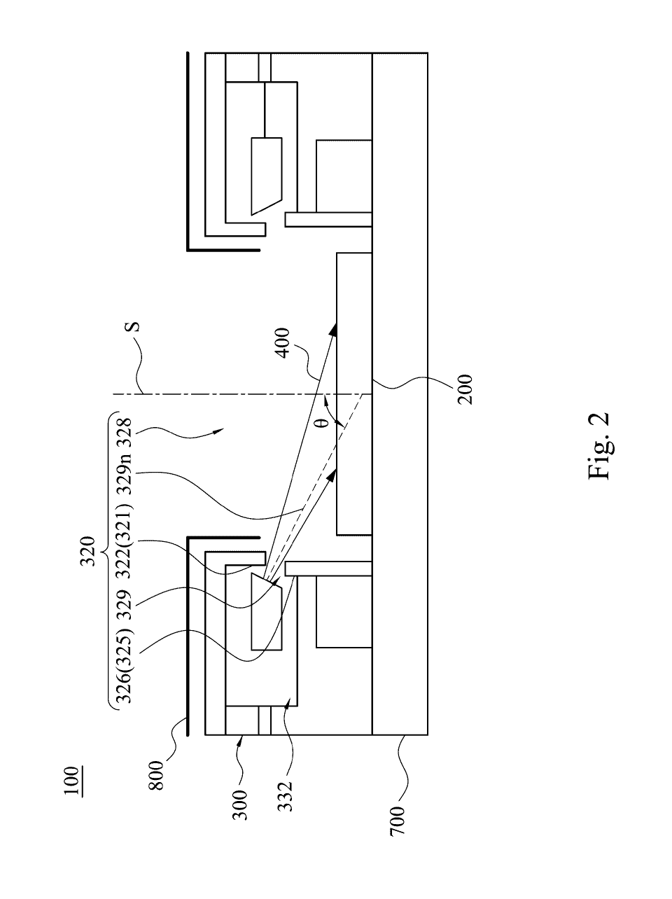

FIG. 1 is a schematic perspective view of an ion beam sputter deposition module 100 utilizing an anode layer ion source 300 according to one embodiment of this invention. FIG. 2 is a cross-sectional view viewed along line 2-2 of FIG. 1. As shown in FIG. 1 and FIG. 2, an ion beam sputter deposition module 100 is provided. The ion beam sputter deposition module 100 includes a target 200 and an anode layer ion source 300. The anode layer ion source 300 provides an ion beam 400 to be emitted on the target 200 in an inclined angle. A substrate for materials to be deposited (not shown in Figs.) is disposed directly above the target 200.

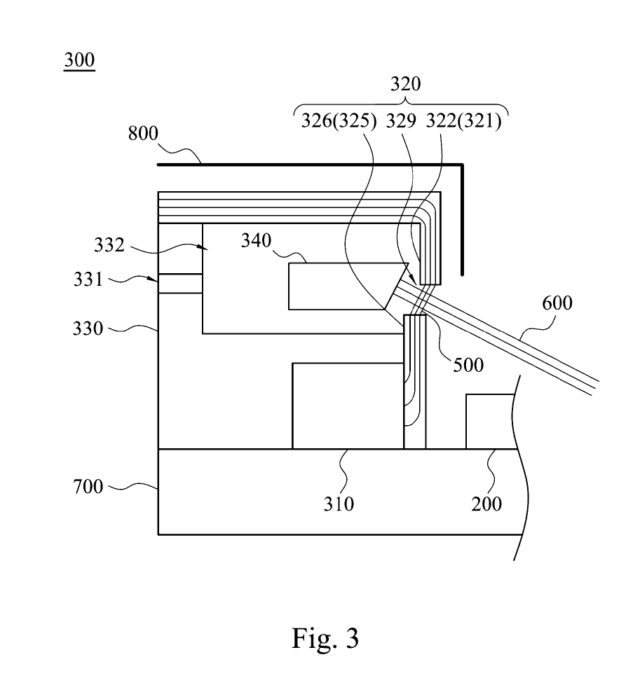

FIG. 3 is a partially enlarged view of FIG. 2. As shown in FIG. 3, the anode layer ion source 300 includes a magnetic field generating member 310, a cathode electrode 320, a case member 330, and an anode electrode 340. The magnetic field generating member 310 generates a magnetic field 500. The cathode electrode 320 includes an upper cathode electrode 321 and a lower cathode electrode 325. The upper cathode electrode 321 has a first end member 322. The lower cathode electrode 325 has a second end member 326. An opening 329 is formed between the first end member 321 and the second end member 325, and the first end member 322 and the second end member 326 are two ends of the opening 329. The cathode electrode 320 guides the magnetic field 500 generated by the magnetic field generating member 310 to the opening 329, and the magnetic field 500 in the opening 329 is substantially parallel to the connection of the two ends of the opening 329. The case member 330 and the cathode electrode 320 form an accommodating cavity 332. The case member 330 can be grounded or floated. The anode electrode 340 is disposed in the accommodating cavity 332 and generates an electric field 600 to the opening 329. The electric field 600 in the opening 329 is substantially perpendicular to the magnetic field 500 in the opening 329. It is noted that directions of the magnetic field 500 and the electric field 600 are illustrative, and the directions of the magnetic field 500 and the electric field 600 in actual situations may be slightly different from the directions of the magnetic field 500 and the electric field 600 shown in FIG. 3.

Specifically, the potentials of the anode electrode 340 and the cathode electrode 320 are greater than zero. Embodiments of this disclosure are not limited thereto. The person having ordinary skill in the art can make proper modifications to the anode electrode 340 and cathode electrode 320 depending on the actual application.

As shown in FIG. 2 and FIG. 3, when the anode layer ion source 300 generates the ion beam 400, first, the vacuum chamber where the ion beam sputter deposition module 100 is positioned is vacuumed, and working gas such as argon is filled into the module through opening 331. Then, the electric field 600 is generated to the opening 329. Because the magnetic field 500 generated by the magnetic generating member 310 is guided to the opening 329, and the magnetic field 500 in the opening 329 is substantially parallel to the connection of the two ends of the opening 329, electrons will moves in a helical trajectory toward the anode electrode 340 due to the influence of the magnetic field 500 and the electric field 600. When the electrons are moving, some of the electrons will hit argon atoms, such that positive argon ions are generated. Positive argon ions will be pushed away from the anode electrode 340 due to the influence of the electric field 600, such that the ion beam 400 is formed.

Because the potential of the cathode electrode 320 is greater than zero, the cathode electrode 320 generates outwardly diverging electric fields as well. Therefore, when ions (positively charged) move away from the anode electrode 340, at first some of the ions may move toward the cathode electrode 320. However, ions will be repelled by the cathode electrode 320 due to the electric fields generated by the cathode electrode 320 such that ions will not hit the cathode electrode 320. Therefore, because ions do not hit the cathode electrode 320, the cathode electrode 320 will not be damaged. Meanwhile, because no ions are wasted, the sputtering efficiency is effectively enhanced.

Further, only direct current power supply is needed to be the power supply of the ion beam sputter deposition module 100 to complete all kinds of the required sputterings (for example, the metal film sputtering or the insulation film sputtering). Compared to the conventional magnetron sputtering module, which usually uses alternating current power supply as its power source, the manufacturing cost of direct current power supply of the ion beam sputter deposition module 100 is much lower than the manufacturing cost of the alternating current power supply. In addition, because the operating power of the direct current power supply of the ion beam sputter deposition module 100 is much lower than the operating power of the alternating current power supply of the conventional magnetron sputtering module (for example, the ion beam sputter deposition module 100 and the conventional magnetron sputtering module provide approximately the same sputtering quality when the power of the direct current power supply of the ion beam sputter deposition module 100 is 10 watts and the power of the alternating current power supply (13.5 MHz) of the conventional magnetron sputtering module is 70 watts to 80 watts), the electricity needed for the sputtering is reduced, such that the sputtering cost can be further reduced.

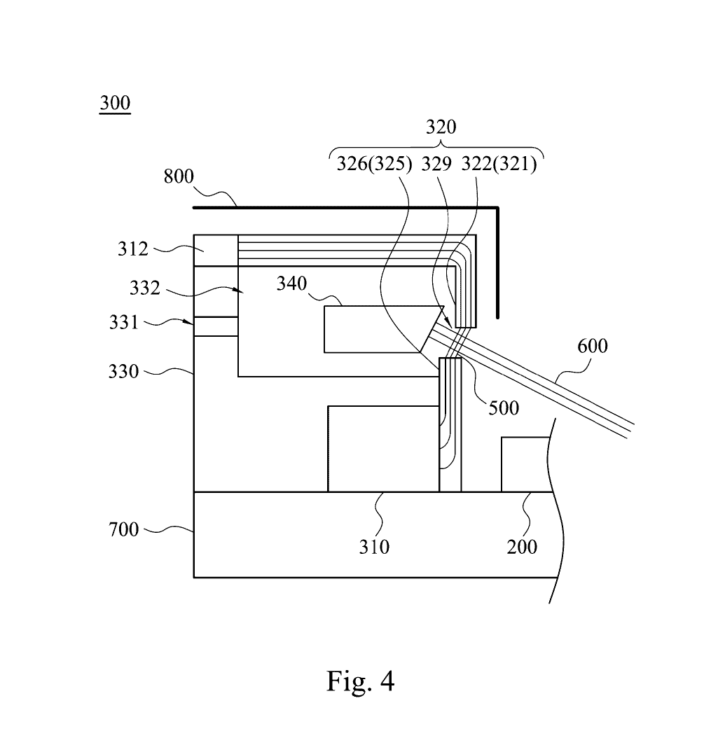

FIG. 4 is a schematic perspective view of the anode layer ion source 300 according to another embodiment of this invention. As shown in FIG. 4, the anode layer ion source 300 further includes a magnetic field generating member 312. The magnetic field generating member 312 cooperates with the magnetic generating member 310 to generate the magnetic field 500. Embodiments of this disclosure are not limited thereto. In other embodiments, the anode layer ion source 300 may only include the magnetic field generating member 312, and the anode layer ion source 300 does not include the magnetic field generating member 310.

The magnetic field generating members 310 and 312 may be permanent magnets or electromagnets. In addition, when the magnetic field generating members 310 and 312 are electromagnets, the potentials of the magnetic field generating members 310 and 312 and the cathode electrode 320 need not to be the same. Specifically, because the function of the magnetic field generating members 310 and 312 is to generate the magnetic filed 500, and the function of the cathode electrode 320 is to guide magnetic field 500 to the opening 329 and generate outwardly diverging electric field to repel the ions, such that the ions will not hit the cathode electrode 320, the function of the magnetic field generating members 310 and 312 is different from the function of the cathode electrode 320. Therefore, the potentials of the magnetic field generating members 310 and 312 and the cathode electrode 320 need not to be the same.

Specifically, the cathode electrode 320 are made of a material that is both magnetoconductive and electrical conductive that act as electrostatic-magnetic wehnelt electrode. Embodiments of this disclosure are not limited thereto. The person having ordinary skill in the art can make proper modifications to the cathode electrode 320 depending on the actual application.

Therefore, the cathode electrode 320 guides the magnetic field 500 to the opening 329 by the magnetoconductive material properties. And, the reason why the cathode electrode 320 is electrically connected to the external power supply is to generate outwardly diverging electric field to repel positive ions.

Specifically, the shapes of the first end member 322 and the second end member 326 are annular, oval or racetrack shaped, such that the shape of the opening 329 becomes a side surface of a virtual column (see FIG. 1) and the opening 329 faces the cylinder axis of the virtual column. Meanwhile, the upper cathode electrode 321, the lower cathode electrode 325, and the anode layer ion source 300 may be annular, oval or racetrack shaped structures as well.

Therefore, because the opening 329 is substantially annular, oval or racetrack shaped the ion beam 400 moves to the target 200 from different directions, such that the distribution of the ion beam 400 is symmetric. Therefore, the thicknesses of different parts of the thin film deposited on the substrate are approximately the same.

Specifically, the normal 329n of the opening 329 (the normal 329n is basically perpendicular to the connection of the two ends of the opening 329) is not perpendicular to a symmetry axis S of the first end member 322, or the normal 329n of the opening 329 is not perpendicular to the cylinder axis of the aforementioned virtual column. In addition, the symmetry axis S may be the symmetry axis of the second end member 322, the upper cathode electrode 321, the lower cathode electrode 325, the anode layer ion source 300, or the ion beam sputter deposition module 100.

Because the normal 329n is approximately parallel to the moving direction of the ion beam 400, and the symmetry axis S is perpendicular to the top surface of the target 200, the ion beam 400 is emitted to the target 200 in at an inclined angle. Then, because the ion beam 400 is emitted to the target 200 in an inclined angle, the target 200 can be sputtered and deposited on substrates positioned upstream of the target 200. Therefore, the target 200 and the anode layer ion source 300 are effectively integrated, the total volume of the accommodating space 328 and the accommodating cavity 332 is smaller than the volume needed for accommodating similar components in the conventional ion beam sputtering module. Then, a smaller vacuum pump is needed for the ion beam sputter deposition module 100.

The angle θ between the normal 329n of the opening 329 and the symmetry axis S is in a range from about 30 to about 65 or in a range from about 55° to about 65°. In other words, the incident angle in which the ion beam 400 is emitted on the target 200 may be in a range from about 30° to about 65° or in a range from about 55′ to about 65°. Therefore, in the aforementioned condition, after the target 200 is hit by the ion beam 400, the target 200 can emit the sputtering material in the maximum efficiency, such that the sputtering efficiency is effectively enhanced. The angle θ between the normal 329n of the opening 329 and the symmetry axis S may further be about 60°.

In the aforementioned embodiments, the potentials of the upper cathode electrode 321 and the lower cathode electrode 325 are substantially the same. Embodiments of this disclosure are not limited thereto. In other embodiments, the potential of the upper cathode electrode 321 is different from the potential of the lower cathode electrode 325. Therefore, by adjusting the potentials of the upper cathode electrode 321 and the lower cathode electrode 325, the incident angle in which the ion beam 400 is emitted on the target 200 can be adjusted to optimize deposition efficiency.

As shown in FIG. 4, the case member 330 further includes inlet 331. Therefore, when the accommodating cavity 332 and its surrounding is vacuumed, inert gas such as argon can enter the accommodating cavity 332 through the inlet 331.

As shown in FIG. 2, the ion beam sputter deposition module 100 further includes a heat-dissipating base 700 and a shielding structure 800. The target 200 and the anode layer ion source 300 are both disposed on the heat-dissipating base 700. The shielding structure 800 is disposed above and covers the cathode electrode 320, and the shielding structure 800 is not electrically connected to the cathode electrode 320. The shield structure 800 shields the electric field generated by the cathode electrode 320, and the shield structure 800 can be grounded.

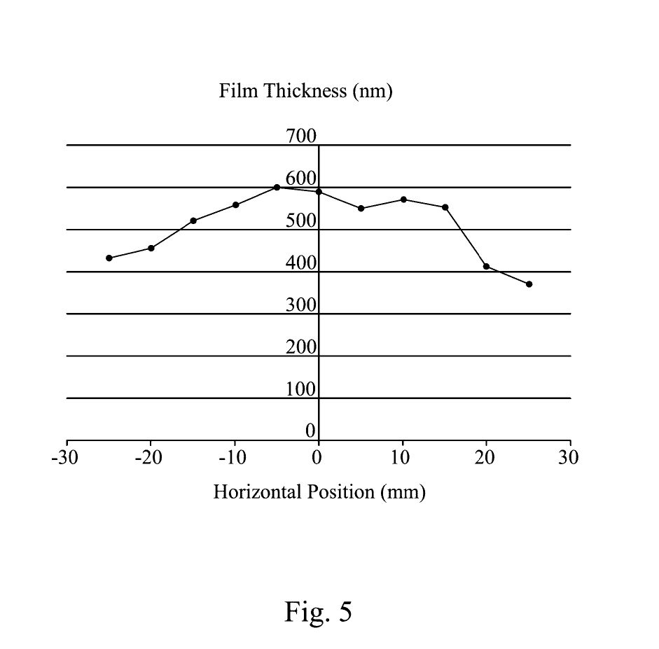

FIG. 5 is a film thickness to horizontal position figure of a thin film deposited on a substrate by the ion beam sputter deposition module 100 according to one embodiment of this invention. In the embodiment, the ion beam sputter deposition module 100 is positioned in a vacuum chamber and pumped down to 2×10⁻⁵ torr. Argon gas enters the accommodating cavity 332 through the inlet 331, and the flow rate of the argon gas is 2.6 sccm (standard cubic centimeters per minute). The potential of the anode electrode 340 is 1000 volts. The discharge current of the anode electrode 340 is 10 mA. The target 200 is made of copper (purity=99.99%). The substrate to be sputtered is made of glass, and the distance between the substrate and the target 200 is 65 mm. The sputtering time is 3 hours. As shown in FIG. 5, the thickness of the thin film deposited on the substrate is in a range from about 400 nm to 600 nm, and the deviation is approximately less than 20%.

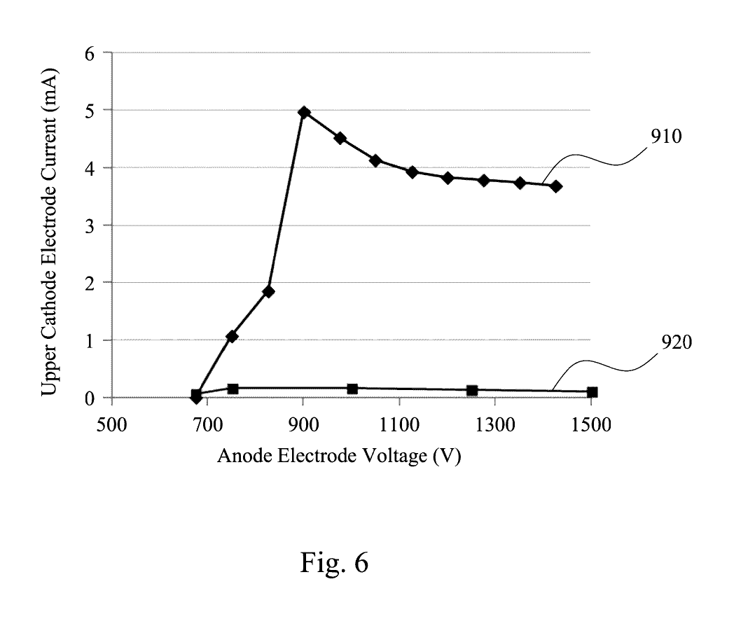

FIG. 6 is a figure showing currents collected by the upper cathode electrode due to argon ion bombardment at various anode electrode voltages when the anode layer ion source 300 is sputtering according to different embodiments of this invention. It is noted that the parameters described above will not repeated again. The connections 910 and 920 respectively represent the relation between the current of the upper cathode electrode 321 and the potential of the anode electrode 340 in two embodiments. In the two embodiments, the flow rate of the argon gas is 3 sccm. In the embodiment corresponding to the connection 910, the upper cathode electrode 321 is grounded. As shown in FIG. 6, when the potential of the anode electrode 340 is increased from 700 volts to 1500 volts, the current generated by argon ions hitting the upper cathode electrode 321 is increased from 0 mA to 5 mA and then decreased to 4 mA. In the embodiment corresponding to the connection 920, a bias voltage is applied to the upper cathode electrode 321, such that the potential of the upper cathode electrode 321 is not zero. As shown in FIG. 6, when the potential of the anode electrode 340 is increased from 700 volts to 1500 volts, the current generated by the ions hitting the upper cathode electrode 321 keeps under 0.2 mA. Therefore, when the potential of the upper cathode electrode 321 is greater than zero, the probability that the ions hit the upper cathode electrode 321 can be effectively reduced.

Because the potential of the cathode electrode 320 is greater than zero, the cathode electrode 320 generates outwardly diverging electric fields. Therefore, when ions move away from the anode electrode 340, at first some of the ions may move toward the cathode electrode 320. However, ions will be repelled by the cathode electrode 320 due to the electric fields generated by the cathode electrode 320 when the distance between the ions and the cathode electrode 320 become smaller, such that ions will not hit the cathode electrode 320. Therefore, because ions do not hit the cathode electrode 320, the anode layer ion source 300 will not overheated, and the cathode electrode 320 will not be damaged by ion bombardment. Meanwhile, because no ions are wasted, the sputtering efficiency is effectively enhanced.

The upper cathode electrode 321 and the lower cathode electrode 325 do not have to be at the same potential. These two cathode electrodes together act as an electrostatic-magnetic wehnelt electrode. The potential on 321 and 325 can be adjusted by separate power supplies, while their geometrical shape can also be adjusted that the number of ions impinging on the target can be maximized while ions hitting the cathode can be mimimized.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. An anode layer ion source, comprising:
a magnetic field generating member configured to generate a magnetic field;
a cathode electrode, comprising:
an upper cathode electrode having a first end member; and
a lower cathode electrode having a second end member, wherein an opening is formed between the first end member and the second end member, the first end member and the second end member are two ends of the opening, the cathode electrode guides the magnetic field generated by the magnetic field generating member to the opening, and the magnetic field in the opening is substantially parallel to the connection of the two ends of the opening;
a case member, wherein the case member and the cathode electrode form an accommodating cavity; and
an anode electrode disposed in the accommodating cavity and configured to generate an electric field to the opening, wherein the electric field in the opening is substantially perpendicular to the magnetic field in the opening.

2. The anode layer ion source of claim 1, wherein potentials of the anode electrode and the cathode electrode are greater than zero.

3. The anode layer ion source of claim 1, wherein a potential of the upper cathode electrode is different from a potential of the lower cathode electrode

4. The anode layer ion source of claim 1, wherein the magnetic field generating member is a permanent magnet.

5. The anode layer ion source of claim 1, wherein the magnetic field generating member is an electromagnet.

6. The anode layer ion source of claim 1, wherein the cathode electrode is made of a material that is both magnetoconductive and electrical conductive.

7. The anode layer ion source of claim 1, wherein shapes of the first end member and the second end member are annular, oval or racetrack shaped.

8. The anode layer ion source of claim 7, wherein a normal of the opening is not perpendicular to a symmetry axis of the first end member.

9. An ion beam sputter deposition module, comprising:
a target; and
the anode layer ion source of claim 7 configured to provide an ion beam to be emitted on the target in an inclined angle.

10. The ion beam sputter deposition module of claim 9, wherein an incident angle in which the ion beam is emitted on the target is in a range from about 30′ to about 65′.
